(19) United States
(12) Patent Application Publication
(10) Pub. No.: US 2015/0279983 A1
(43) Pub. Date: Oct. 1, 2015

(54) SEMICONDUCTOR DEVICE

(71) Applicant: SANKEN ELECTRIC CO., LTD., Niiza-Shi (JP)

(72) Inventors: Yuki TANAKA, Fujimi-Shi (JP); Toru YOSHIE, Tokyo (JP)

(21) Appl. No.: 14/663,603

(22) Filed: Mar. 20, 2015

(30) Foreign Application Priority Data
Mar. 25, 2014 (JP) 2014-061151

(51) Int. Cl. H01L 29/78; H01L 27/07; H01L 29/36; H01L 29/47; H01L 29/872

(52) U.S. Cl. CPC H01L 29/7806; H01L 29/47; H01L 29/8725; H01L 29/36; H01L 27/0727

(57) ABSTRACT

A semiconductor device is provided that comprises first semiconductor region of a first conductivity type, a second semiconductor region of a second conductivity type on the first semiconductor region, a third semiconductor region of the first conductivity type above the second semiconductor region, a gate insulating film on the second semiconductor region between the third semiconductor region and the first semiconductor region, a gate electrode provided along the second semiconductor region with the gate insulating film interposed therebetween, a Schottky electrode on the first semiconductor region exposed at a bottom of a trench extending from an upper surface of the third semiconductor region and reaching the first semiconductor region, and a first main electrode electrically connected to the Schottky electrode and the third semiconductor region. A Schottky barrier diode is arranged on an interface between the Schottky electrode and the first semiconductor region.

### CROSS REFERENCE TO RELATED APPLICATIONS

This application claims priority based on 35 USC 119 from prior Japanese Patent Application No. 2014-061151 filed on Mar. 25, 2014, entitled “SEMICONDUCTOR DEVICE”, the entire contents of which are hereby incorporated by reference.

### BACKGROUND

The disclosure relates to a semiconductor device including a reflux diode.

When a MOS field-effect transistor (MOSFET) is used in an inverter device or the like, there is a method utilizing a body diode (PN diode), which is parasitically formed in the MOSFET, as a reflux diode. However, particularly in the case of using a silicon carbide (SiC) substrate, the PN diode has a forward voltage (VF) as high as about 3 V. Moreover, there arises a problem such as a poor breakdown voltage due to deterioration in forward current of the body diode.

Therefore, there has been a study on a semiconductor device using a Schottky barrier diode (SBD) having a low forward voltage VF as a reflux diode that is inverse-parallel connected to a MOSFET (see, for example, Japanese Patent Application Publication No. 2011-14740 (Patent Document 1)).

### SUMMARY

However, when a chip having a transistor mounted thereon and a chip having a SBD mounted thereon are parallel connected, a semiconductor device is increased in size. Moreover, cost is increased due to the yield of each chip. On the other hand, when the SBD and the transistor are mounted on the same chip, the chip needs a region to form the SBD. Therefore, there is a problem that a chip area is increased. For example, the number of cells in the transistor is reduced relative to the total chip area combining the transistor and the SBD. Thus, an ARon value represented by (total chip area)×(on-resistance) is increased.

An embodiment of the semiconductor device comprises a first semiconductor region of a first conductivity type, a second semiconductor region of a second conductivity type on the first semiconductor region, a third semiconductor region of the first conductivity type above the second semiconductor region, a gate insulating film on the second semiconductor region between the third semiconductor region and the first semiconductor region, a gate electrode provided along the second semiconductor region with the gate insulating film interposed therebetween, a Schottky electrode on the first semiconductor region exposed at a bottom of a trench extending from an upper surface of the third semiconductor region and reaching the first semiconductor region, and a first main electrode electrically connected to the Schottky electrode and the third semiconductor region, wherein a Schottky barrier diode is arranged on an interface between the Schottky electrode and the first semiconductor region.

### BRIEF DESCRIPTION OF THE DRAWINGS

FIG. 1 is a schematic cross-sectional view illustrating a configuration of a semiconductor device according to an embodiment.

FIG. 2 is an equivalent circuit illustrating the configuration of the semiconductor device according to the embodiment.

FIG. 3 is a schematic step cross-sectional view (Part 1) explaining a method of manufacturing a semiconductor device according to the embodiment.

FIG. 4 is a schematic step cross-sectional view (Part 2) explaining the method of manufacturing a semiconductor device according to the embodiment.

FIG. 5 is a schematic step cross-sectional view (Part 3) explaining the method of manufacturing a semiconductor device according to the embodiment.

FIG. 6 is a schematic step cross-sectional view (Part 4) explaining the method of manufacturing a semiconductor device according to the embodiment.

FIG. 7 is a schematic step cross-sectional view (Part 5) explaining the method of manufacturing a semiconductor device according to the embodiment.

FIG. 8 is a schematic step cross-sectional view (Part 6) explaining the method of manufacturing a semiconductor device according to the embodiment.

FIG. 9 is a schematic step cross-sectional view (Part 7) explaining the method of manufacturing a semiconductor device according to the embodiment.

FIG. 10 is a schematic step cross-sectional view (Part 8) explaining the method of manufacturing a semiconductor device according to the embodiment.

FIG. 11 is a schematic step cross-sectional view (Part 9) explaining the method of manufacturing a semiconductor device according to the embodiment.

FIG. 12 is a schematic step cross-sectional view (Part 10) explaining the method of manufacturing a semiconductor device according to the embodiment.

FIG. 13 is a schematic cross-sectional view illustrating a configuration of a semiconductor device according to a modified example of the embodiment.

### DETAILED DESCRIPTION OF EMBODIMENTS

Next, with reference to the drawings, embodiments are described. In the following description of the drawings, the same or similar parts are denoted by the same or similar reference numerals. However, it should be noted that the drawings are conceptual and ratios of thicknesses of respective layers and the like are different from actual ones. Therefore, specific thicknesses and dimensions should be determined by taking into consideration the following description. Moreover, as a matter of course, also among the drawings, there are included portions in which dimensional relationships and ratios are different from each other.

The following embodiments illustrate devices and methods for embodying a technical idea of the invention. Materials, shapes, structures, arrangements and the like of constituent components of the embodiments do not limit the invention. Various changes can be added to the embodiments of the invention within the scope of claims.

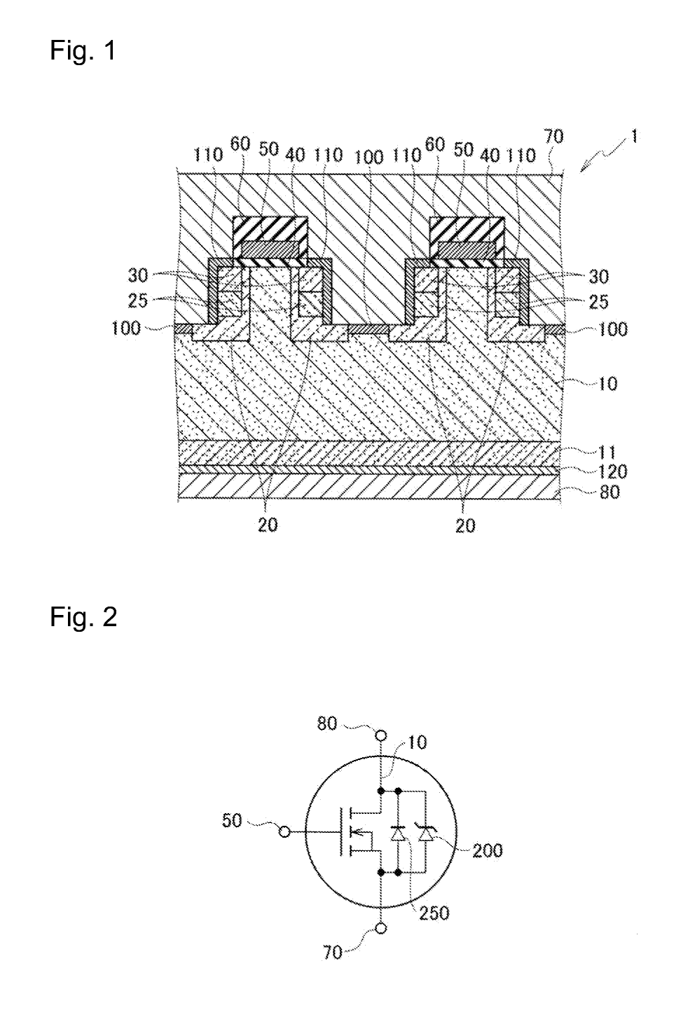

As illustrated in FIG. 1, semiconductor device 1 according to the embodiment includes: first semiconductor region 10 of a first conductivity type; second semiconductor region 20 of a second conductivity type, disposed on first semiconductor region 10; and third semiconductor region 30 of the first conductivity type, disposed above second semiconductor region 20.

As illustrated in FIG. 1, in semiconductor device 1, a trench is formed, which extends from an upper surface of third semiconductor region 30 and reaches first semiconductor region 10, and Schottky electrode 100 is disposed on first semiconductor region 10 exposed at a bottom of the trench. A Schottky barrier diode (SBD) is formed on an interface between Schottky electrode 100 and first semiconductor region 10. Also, first main electrode 70 is disposed so as to come into contact with Schottky electrode 100 and fill up the trench. First main electrode 70 is electrically connected to Schottky electrode 100 and third semiconductor region 30.

Semiconductor device 1 further includes contact region 25 of the second conductivity type, which is disposed on a side surface of the trench between second semiconductor region 20 and third semiconductor region 30. Third semiconductor region 30 and contact region 25 are electrically connected by side surface electrode 110 disposed along the side surface of the trench. Contact region 25 is higher in impurity concentration than second semiconductor region 20. Second semiconductor region 20 and third semiconductor region 30 are securely ohmically connected through p-type contact region 25. First main electrode 70 buried in the trench is electrically connected to third semiconductor region 30 through side surface electrode 110.

The first conductivity type and the second conductivity type are opposite to each other. More specifically, the second conductivity type is a p type if the first conductivity type is an n type, and the second conductivity type is the n type if the first conductivity type is the p type. The following description is given of, as an example, the case where the first conductivity type is the n type and the second conductivity type is the p type.

Semiconductor deice 1 illustrated in FIG. 1 is a MOSFET. In the following description, it is assumed for the purpose of illustration that first semiconductor region 10 is n-type drift region 10, second semiconductor region 20 is p-type base region 20, third semiconductor region 30 is n-type source region 30, and first main electrode 70 is source electrode 70.

In semiconductor device 1, gate insulating film 40 is disposed on base region 20 between source region 30 and drift region 10. Also, gate electrode 50 is disposed along base region 20 with gate insulating film 40 interposed therebetween. Side and upper surfaces of gate electrode 50 are covered with interlayer insulating film 60. While source electrode 70 is disposed on the upper surface of semiconductor device 1, gate electrode 50 and source electrode 70 are electrically insulated from each other by interlayer insulating film 60.

Note that drift region 10 is formed on semiconductor substrate 11. Semiconductor substrate 11 is a silicon (Si) substrate, an SiC substrate or the like, for example. Drift region 10 is formed by epitaxial growth on n-type semiconductor substrate 11, for example. On a back surface of semiconductor substrate 11, which is opposite to the surface on which drift region 10 is disposed, drain electrode 80 that is a second main electrode is disposed.

FIG. 2 illustrates an equivalent circuit diagram of semiconductor device 1. SBD 200 is connected between source electrode 70 and drift region 10 by Schottky electrode 100 formed at the bottom of the trench. SBD 200 has an anode connected to source electrode 70 and a cathode connected to drift region 10. The MOSFET and SBD 200 in semiconductor device 1 are inverse-parallel connected, and SBD 200 functions as a reflux diode. Note that diode 250 illustrated in FIG. 2 is a PN diode parasitically formed in the MOSFET.

The use of the SBD as the reflux diode in semiconductor device 1 improves recovery characteristics of the diode compared with the case where the PN diode parasitic to the MOSFET is used as the reflux diode. Thus, switching characteristics of semiconductor device 1 are improved. Moreover, since the SBD is included in a chip having the MOSFET formed therein, increases in device size and cost are suppressed.

More specifically, SBD 200 is disposed at the bottom of the trench formed inside a semiconductor base having the MOSFET formed therein. The trench is formed between base regions 20, and the SBD is disposed between adjacent MOSFETs. Since the SBD is formed at the bottom of the trench, an increase in area of the semiconductor device is suppressed compared with the case where a MOSFET and a SBD are electrically connected on a surface of a semiconductor base in a planar MOSFET.

Furthermore, source region 30 and contact region 25 are laminated, and side surface electrode 110 is disposed on the side surface of the laminated body. Thus, base region 20 and source region 30 are securely ohmically connected, and the increase in area is further suppressed.

Therefore, semiconductor device 1 illustrated in FIG. 1 can suppress an increase in chip area while using a SBD as a reflux diode that is inverse-parallel connected to a transistor. Thus, an increase in ARon value of the transistor itself is suppressed.

An example of a method of manufacturing semiconductor device 1 is described below. Note that, as a matter of course, the manufacturing method described below is an example, and semiconductor device 1 can be realized using various other formation methods including the modified example.

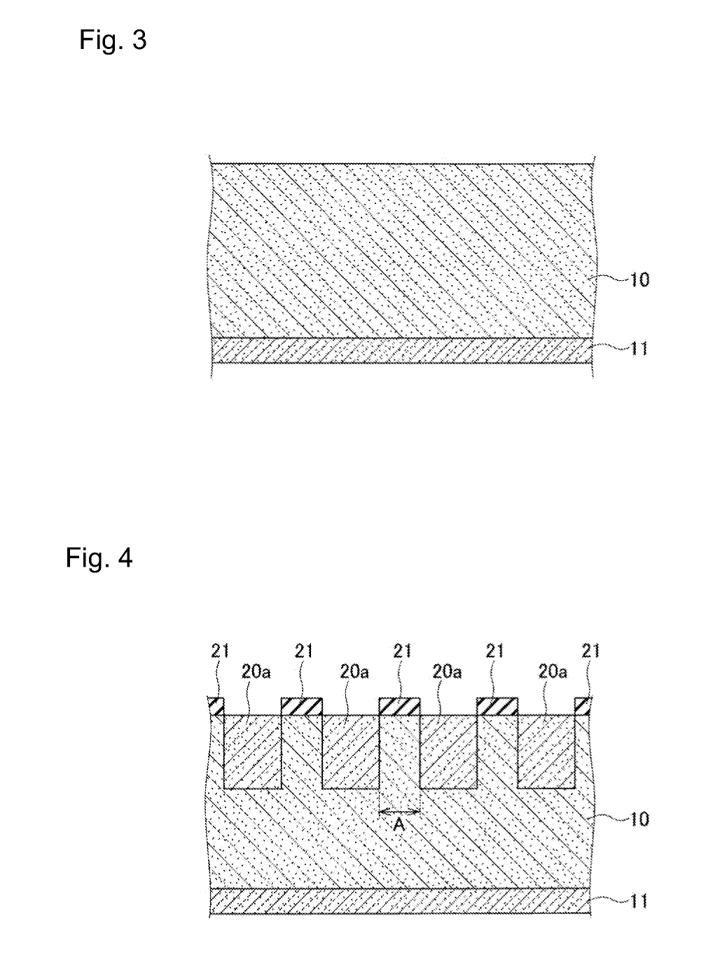

First, a semiconductor base as illustrated in FIG. 3 is prepared by epitaxially growing drift region 10 on semiconductor substrate 11. An SiC substrate or the like can be employed as semiconductor substrate 11.

Then, base formation region 20a is formed, as illustrated in FIG. 4, by implanting p-type impurities into a region where base region 20 is to be formed. For example, implantation mask 21 is formed by patterning a photoresist film having a thickness of about 2 μm, for example. “Ion implantation mask” is a mask covering a surface of a region where no ion implantation is performed. Using implantation mask 21, aluminum (Al) ions are implanted. Ion implantation conditions include, for example, ion implantation energy of 280 to 700 KeV and an implantation dose of 8E13 cm⁻². In this event, no ion implantation is performed in a region where SBD 200 is to be formed, which is indicated by width A in FIG. 4. More specifically, base formation regions 20a are formed spaced apart from each other.

Note that the ion implantation may be performed in stages while changing the ion implantation energy and implantation dose. By such stepwise ion implantation, an impurity concentration profile can be arbitrarily set. For example, an impurity concentration in a surface of base formation region 20a is set low, while an impurity concentration in a deep position is set high. A threshold voltage of semiconductor device 1 can be lowered by reducing a surface concentration of base region 20.

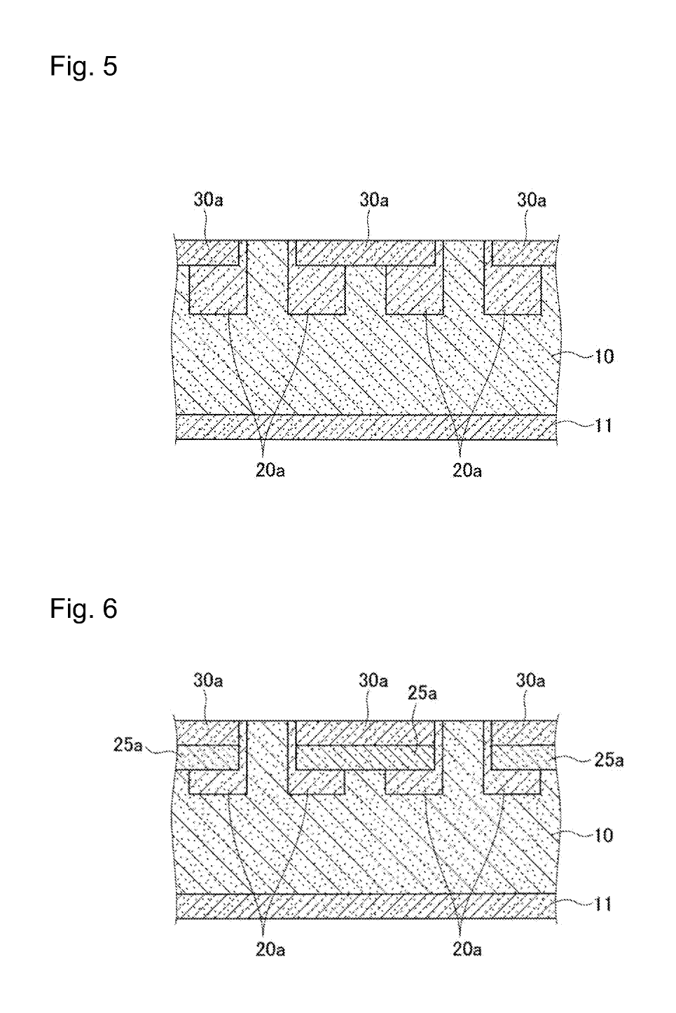

After implantation mask 21 is removed, n-type impurities are implanted into a region where source region 30 is to be formed, thereby forming source formation regions 30a as illustrated in FIG. 5. Under ion implantation conditions including, for example, ion implantation energy of 70 to 200 KeV and an implantation dose of 1.05E15 cm⁻², phosphorus (P) ions are implanted in stages. Furthermore, as illustrated in FIG. 6, contact formation regions 25a are formed by implanting p-type impurities into a region where contact region 25 is to be formed. More specifically, each of contact formation regions 25a is formed in contact with a lower surface of source formation region 30a so as to form a laminate structure with source formation region 30a. Under ion implantation conditions including, for example, ion implantation energy of 250 to 500 KeV and an implantation dose of 2.5E15 cm⁻², Al ions are implanted in stages. As an implantation mask for the ion implantation of source formation region 30a and contact formation region 25a, a photoresist film having a thickness of about 1.3 μm, or the like can be employed.

Note that, for the formation of base formation region 20a, source formation region 30a and contact formation region 25a, the ion implantation may be performed at high temperature using an insulating film, such as an oxide film, as the implantation mask.

After the ion implantation into base formation region 20a, source formation region 30a and contact formation region 25a, a carbon layer (not illustrated) such as a resist film is formed on the entire surface to perform activation annealing for 2 to 10 minutes at a temperature of about 1600 to 1800° C. Thus, base region 20, source region 30 and contact region 25 are formed.

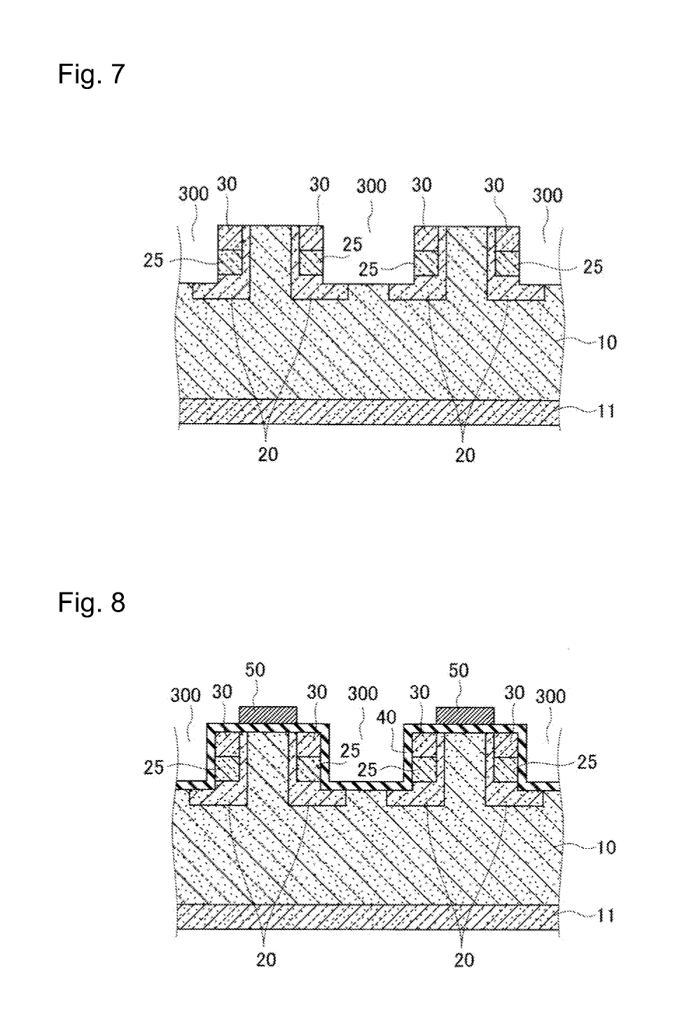

After the carbon layer is removed by oxygen (O₂) asking or the like, trenches 300 are formed as illustrated in FIG. 7 by photolithography and etching, for example. Each of trenches 300 has its tip extending from an upper surface of source region 30 and reaching drift region 10. For example, trench 300 that penetrates source region 30 and contact region 25 is formed by dry etching using carbon tetrafluoride (CF₄) gas, sulfur hexafluoride (SF₆) or the like in a state where an upper surface of a region where no trench 300 is to be formed is protected with a photoresist film having a thickness of about 3 μm, or the like. Thus, an upper surface of drift region 10 is exposed at a bottom of trench 300. The width and depth of the trench depends on the thicknesses of base region 20, source region 30 and contact region 25, an area of the MOSFET, and the like. For example, trench 300 has a depth of about 600 nm or more and a width of about 1 to 3 μm.

Note that trench 300 is formed by etching a region including the region where no base region 20 is to be formed, which is indicated by width A in FIG. 4. Therefore, trench 300 is formed so as to penetrate at least source region 30 and contact region 25. Thus, even if the depth of the tip of trench 300 does not reach the depth of base region 20, the upper surface of drift region 10 is exposed at the bottom of trench 300.

Next, gate insulating film 40 having a thickness of about 50 nm is formed on the entire surface by thermal oxidation, CVD or the like. Then, a polysilicon film is deposited on the entire surface of gate insulating film 40, and phosphorus (P) and boron (B) are implanted. Thereafter, gate electrode 50 is formed at a predetermined position on gate insulating film 40 as illustrated in FIG. 8 by patterning the polysilicon film.

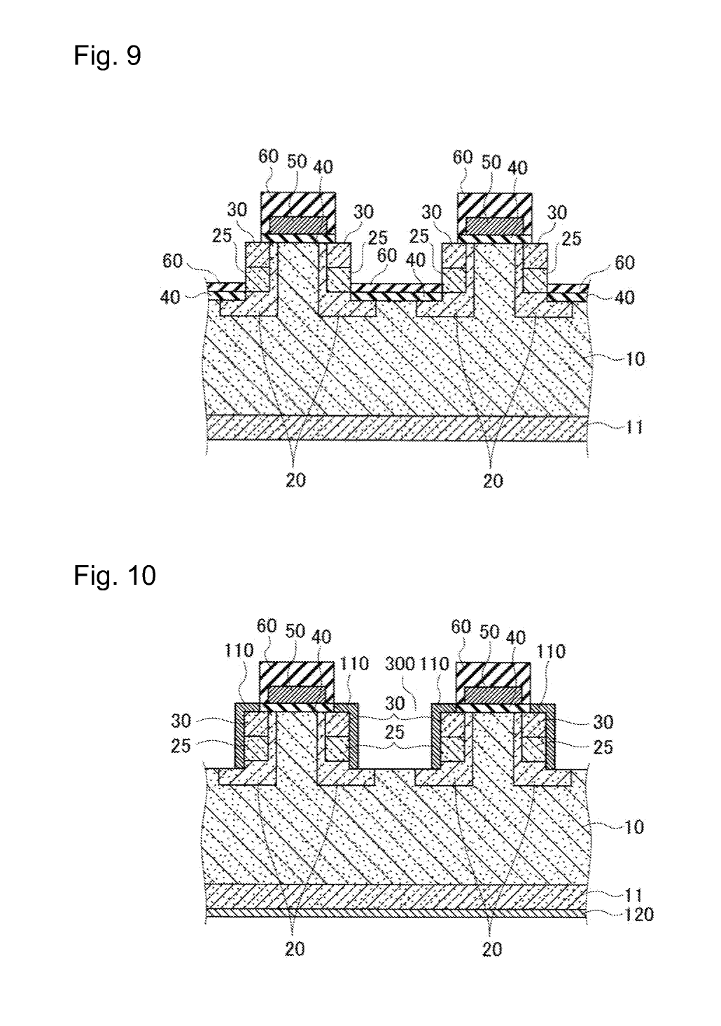

Subsequently, a silicon oxide film having a thickness of about 800 nm is formed on the entire surface by CVD or the like as interlayer insulating film 60. Then, interlayer insulating film 60 buried in trench 300 is removed by etching to expose side surfaces of source region 30 and contact region 25 as illustrated in FIG. 9. For example, interlayer insulating film 60 is etched by dry etching using a photoresist film having a thickness of about 3 μm as an etching mask and using CF₄ gas, methane trifluoride (CHF₃) gas or the like.

In this event, the insulating film is left at the bottom of trench 300 in order to prevent a reaction between the surface of drift region 10 and a nickel (Ni) film at the bottom of trench 300 during contact annealing to be described later. Next, Ni films, each having a thickness of about 50 to 100 nm, are formed on the front and back surfaces of the semiconductor base. Then, contact annealing is performed at 950° C. for 2 minutes, and thus side surface electrode 110 made of Ni silicide is formed on the side surface of trench 300. More specifically, side surface electrode 110 is formed by silicidizing the side surfaces of source region 30 and contact region 25 exposed on the side surface of trench 300. At the same time, Ni silicide film 120 is formed at the bottom of semiconductor substrate 11.

Thereafter, the unreacted Ni film remaining on interlayer insulating film 60 is removed with persulfate or the like. Then, as illustrated in FIG. 10, the insulating film at the bottom of trench 300 is removed by dry etching using CF₄ gas, CHF₃ gas or the like.

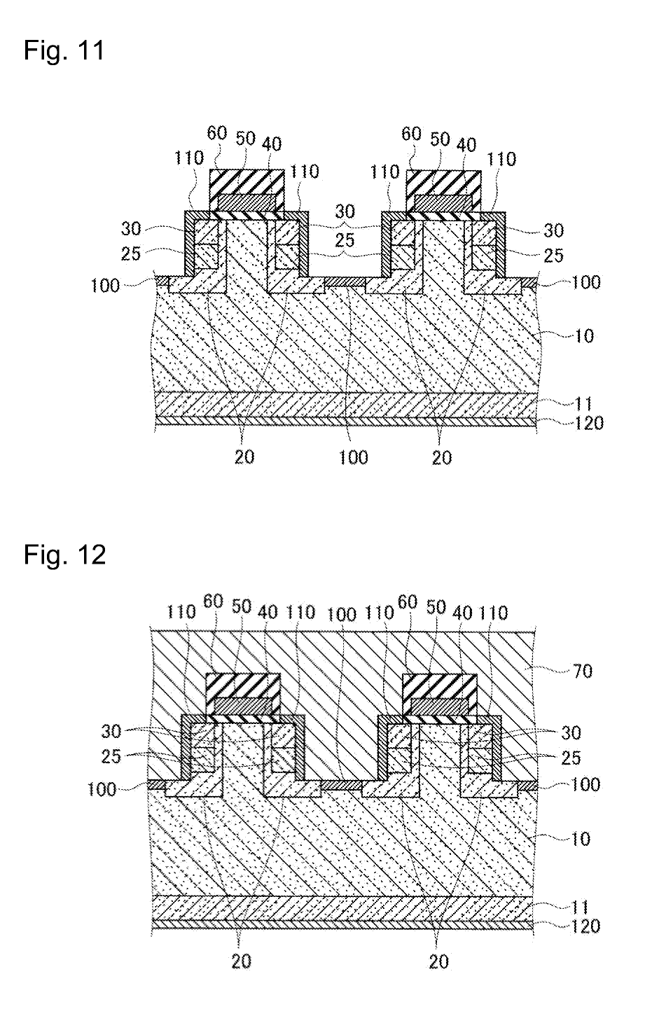

Next, as illustrated in FIG. 11, Schottky electrode 100 is formed on the surface of drift region 10 exposed at the bottom of trench 300. For example, after a molybdenum (Mo) film having a thickness of 50 to 100 nm is formed on the entire surface, the Mo film is patterned by photolithography and etching so as to be disposed on drift region 10 at the bottom of trench 300. Then, annealing is performed at 650° C. for 10 minutes to form Mo silicide. More specifically, Schottky electrode 100 is formed by silicidizing the surface of drift region 10 exposed at the bottom of trench 300.

As described above, SBD 200 is formed, having Mo as Schottky metal at the bottom of trench 300. Note that, for patterning of the Mo film, a photoresist film having a thickness of about 1.5 μm, for example, is patterned and used as an etching mask. Alternatively, the Mo film may be patterned by using a lift-off technique in which an Mo film is formed on a patterned photoresist film and unnecessary MO film is removed together with the photoresist film.

Next, a metal film of a titanium (Ti)/Al laminated body or the like is formed on the surface by deposition, sputtering or the like. Then, the metal film is patterned using a photoresist film having a thickness of about 3 μm as an etching mask, and thus a surface electrode such as source electrode 70 is formed as illustrated in FIG. 12. In this event, although not illustrated, interlayer insulating film 60 is partially removed by etching to form an opening in a contact region with gate electrode 50. Thus, a surface electrode to be connected with gate electrode 50 is also formed.

Thereafter, drain electrode 80 of a titanium (Ti)/Ni/Al laminated body or the like is formed by deposition, sputtering or the like on Ni silicide film 120 on the back surface of semiconductor substrate 11. Thus, semiconductor device 1 is completed.

As described above, in the method of manufacturing semiconductor device 1 according to the embodiment, SBD 200 is formed at the bottom of the trench formed between adjacent MOSFETs. Thus, an increase in area of the semiconductor device is suppressed. Furthermore, source region 30 and contact region 25 are laminated, and side surface electrode 110 is formed on the side surface of the laminated body. Thus, the increase in area of the semiconductor device is further suppressed. Therefore, according to the method of manufacturing semiconductor device 1 described above, an increase in chip area of semiconductor device 1 can be suppressed while using the SBD as a reflux diode that is inverse-parallel connected to the transistor.

### Modified Example

The above description is given of an example where a Schottky junction is formed, in which Schottky electrode 100 and drift region 10 come into contact with each other, at the bottom of trench 300. Thus, trench 300 is formed in such a manner that the bottom of trench 300 is positioned above the bottom of base region 20.

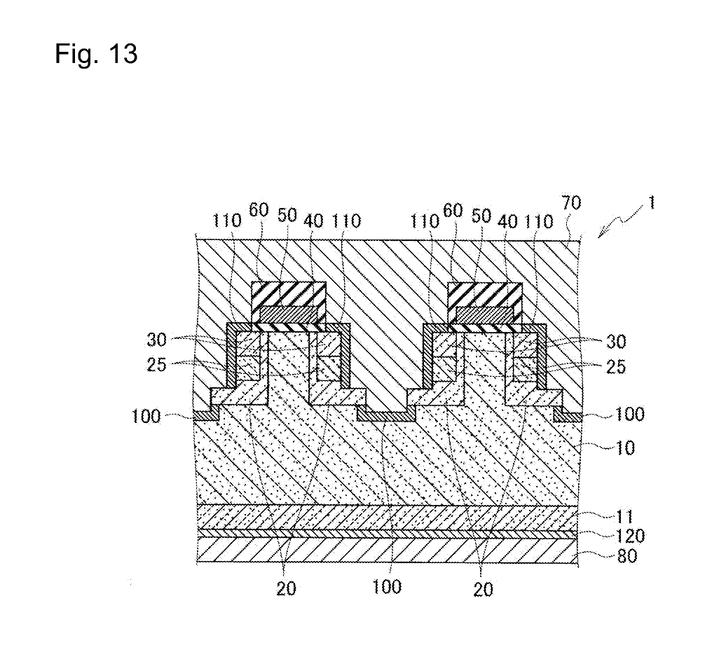

On the other hand, trench 300 may be extended beyond the bottom of base region 20. Then, as illustrated in FIG. 13, Schottky electrode 100 is formed on the surface of drift region 10 exposed not only at the bottom of the trench but also on the side surface of the trench adjacent to the bottom. As a result, Schottky junctions are formed at the bottom and side surface of the trench facing drift region 10. Thus, the area of SBD 200 is increased, and a current flowing through a reflux diode can be increased.

### Other Embodiments

As described above, it should be understood that the invention is not limited to the description and drawings, which constitute a part of this disclosure. From this disclosure, various alternative embodiments, examples and operational technologies will become apparent to those skilled in the art.

For example, the above description is given of, as an example, the case where the transistor included in semiconductor device 1 is the MOSFET having the planar structure. However, the transistor included in semiconductor device 1 may have any other structure.

Moreover, the above description is given of the case where drift region 10 and source region 30 are the n type and base region 20 is the p type. However, drift region 10 and source region 30 maybe the p type and base region 20 maybe the n type.

In this way, embodiments described above provide semiconductor devices capable of suppressing an increase in chip area while using a SBD as a reflux diode that is inverse-parallel connected to a transistor.

As described above, the invention includes various embodiments and the like which are not described herein. Therefore, a technological scope of the invention is defined only by items specific to the invention according to claims pertinent based on the foregoing description.

1. A semiconductor device comprising:
a first semiconductor region of a first conductivity type;
a second semiconductor region of a second conductivity type on the first semiconductor region;
a third semiconductor region of the first conductivity type above the second semiconductor region;
a gate insulating film on the second semiconductor region between the third semiconductor region and the first semiconductor region;
a gate electrode provided along the second semiconductor region with the gate insulating film interposed therebetween;
a Schottky electrode on the first semiconductor region exposed at a bottom of a trench extending from an upper surface of the third semiconductor region and reaching the first semiconductor region; and
a first main electrode electrically connected to the Schottky electrode and the third semiconductor region,
wherein a Schottky barrier diode is arranged on an interface between the Schottky electrode and the first semiconductor region.

2. The semiconductor device according to claim 1, wherein
the first semiconductor region includes a silicided surface that pertains to the Schottky electrode.

3. The semiconductor device according to claim 1, further comprising:
a contact region provided adjacent to a side surface of the trench, arranged between the second semiconductor region and the third semiconductor region, an impurity concentration of the contact region higher than that of the second semiconductor region.

4. The semiconductor device according to claim 3, wherein
the third semiconductor region is electrically connected to the contact region by a side surface electrode along the side surface of the trench.

5. The semiconductor device according to claim 4, wherein
the third semiconductor region includes silicided side surface that pertains to the side surface electrode.

6. The semiconductor device according to claim 4, wherein
the contact region includes silicided side surface that pertains to the side surface electrode.

7. The semiconductor device according to claim 1, wherein
a bottom of trench is positioned above the bottom of the second semiconductor region.

8. The semiconductor device according to claim 1, wherein the trench is extended beyond the bottom of the second semiconductor region.

9. The semiconductor device according to claim 8, wherein
the Schottky barrier diode is arranged on the bottom surface of the trench facing the first semiconductor region and a side surface adjacent to the bottom surface.
